(19) United States
(12) Patent Application Publication
(10) Pub. No.: US 2026/0011707 A1
(43) Pub. Date: Jan. 8, 2026

(54) SEMICONDUCTOR PACKAGE AND METHOD OF FABRICATING THE SAME

(71) Applicant: Samsung Electronics Co., Ltd., Suwon-si (KR)

(72) Inventor: Young-Ja KIM, Suwon-si (KR)

(73) Assignee: Samsung Electronics Co., Ltd., Suwon-si (KR)

(21) Appl. No.: 19/049,714

(22) Filed: Feb. 10, 2025

(30) Foreign Application Priority Data
Jul. 8, 2024 (KR) 10-2024-0089716

(51) Int. Cl. H01L 25/18; H01L 23/00; H01L 23/29; H01L 23/31; H01L 23/538; H01L 25/00

(52) U.S. Cl. CPC H01L 25/18; H01L 23/291; H01L 23/3192; H01L 23/538; H01L 24/08; H01L 24/16; H01L 25/50; H01L 2224/08145; H01L 2224/16227; H01L 2924/37001

(57) ABSTRACT

According to some embodiments, a semiconductor package may include a first semiconductor chip; a second semiconductor chip disposed on a first semiconductor chip; a wall structure disposed on the first semiconductor chip and spaced apart from the second semiconductor chip in a first direction; and a mold layer covering the first and second semiconductor chips, wherein the first semiconductor chip includes a transceiver disposed thereon and spaced apart from the second semiconductor chip, the mold layer has an opening exposing the transceiver, the wall structure is disposed in the opening and is in contact with an inner wall of the mold layer exposed to the opening, the mold layer has a first height, and the wall structure has a second height smaller than the first height.

### CROSS-REFERENCE TO RELATED APPLICATIONS

This U.S. non-provisional patent application claims priority under 35 U.S.C. § 119 to Korean Patent Application No. 10-2024-0089716, filed on Jul. 8, 2024, in the Korean Intellectual Property Office, the entire contents of which are hereby incorporated by reference.

### TECHNICAL FIELD

The present disclosure relates to a semiconductor package and a method of fabricating the same.

### BACKGROUND

Demand on miniaturization and high speed of electronic devices has increased. Accordingly, research is being actively conducted to replace the conventional signal transmission through a metal wiring with an optical signal transmission. Solutions that include optical signal transmission, such as a semiconductor package including an optical integrated circuit in which a light source and an optical coupling element are integrated to transmit an optical signal, are discussed herein.

### SUMMARY

The present disclosure discloses some embodiments including a semiconductor package that operates without optical loss.

The present disclosure also discloses some embodiments that include a method of fabricating a semiconductor package that is capable of increasing yield.

Problems that the present disclosure seeks to solve are not limited to the problems mentioned above, and other problems that are not mentioned may be clearly understood by those skilled in the art from the description below.

A semiconductor package according to some embodiments of the present disclosure includes a second semiconductor chip on a first semiconductor chip, a wall structure on the first semiconductor chip and spaced apart from the second semiconductor chip in a first direction, and a mold layer covering the first and second semiconductor chips, wherein the first semiconductor chip includes a transceiver disposed thereon and not overlapping the second semiconductor chip, the mold layer has an opening exposing the transceiver, the wall structure is disposed in the opening and is in contact with an inner wall of the mold layer exposed to the opening, the mold layer has a first height, and the wall structure has a second height smaller than the first height.

A semiconductor package according to some embodiments of the present disclosure includes an electronic circuit chip on a photonics chip, a wall structure on the photonics chip and spaced apart from the electronic circuit chip, and a semiconductor package including a mold layer covering the photonics chip and the electronic circuit chip, wherein the photonics chip includes a transceiver on an upper portion thereof and not overlapping the electronic circuit chip, the mold layer has an opening that exposes the transceiver, the wall structure is disposed in the opening and is in contact with an inner wall of the mold layer exposed to the opening, and the wall structure does not overlap the transceiver and has a closed ring shape that surrounds the transceiver when viewed in a plan view.

A semiconductor package according to some embodiments of the present disclosure includes a package substrate, a first substrate on the package substrate, first and second semiconductor chips and a photonics chip disposed side by side in a first direction on the first substrate, an electronic circuit chip on the photonics chip, a wall structure on the photonics chip and spaced apart from the electronic circuit chip in the first direction, and a mold layer covering the first and second semiconductor chips, the photonics chip, and the electronic circuit chip, wherein the first semiconductor chip includes semiconductor dies that are sequentially stacked, the photonics chip includes a transceiver on an upper portion thereof and not overlapping the electronic circuit chip, the mold layer has an opening that exposes the transceiver, the wall structure is disposed in the opening and is in contact with an inner wall of the mold layer exposed to the opening, an upper surface of the electronic circuit chip is positioned at the same level as an upper surface of the mold layer, and a step is provided between an upper surface of the mold layer and an upper surface of the wall structure.

A method of fabricating a semiconductor package according to some embodiments of the present disclosure includes preparing a first substrate, mounting first and second semiconductor chips on the first substrate, mounting a photonics chip having an electronic circuit chip bonded to an upper surface thereof on the first substrate, attaching a wall structure spaced apart from the electronic circuit chip on the photonics chip, attaching a support structure on the wall structure by interposing an adhesive member therebetween to form a protection block, and irradiating light to separate the adhesive member and the support structure from the wall structure.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a plan view of an exemplary semiconductor package consistent with some embodiments of the present disclosure.

FIG. 1B is a cross-sectional view taken along line A-A′ of FIG. 1A, consistent with some embodiments of the present disclosure.

FIGS. 2A and 2B are enlarged views of portion ‘P1’ of FIG. 1B, consistent with some embodiments of the present disclosure.

FIG. 3A is a bottom plan view of a protection block, consistent with some embodiments of the present disclosure.

FIGS. 3B, 3C, and 3D are cross-sectional views taken along line B-B′ of FIG. 3A, consistent with some embodiments of the present disclosure.

FIG. 4A is a bottom plan view of a protection block, consistent with some embodiments of the present disclosure.

FIG. 4B is a cross-sectional view taken along line C-C′ of FIG. 4A, consistent with some embodiments of the present disclosure.

FIGS. 5A through 5G are cross-sectional views sequentially showing a fabricating process of a semiconductor package having the cross-section shown in FIG. 1B, consistent with some embodiments of the present disclosure.

FIG. 6 is an enlarged view of portion ‘P2’ of FIG. 5G, consistent with some embodiments of the present disclosure.

FIG. 7 is a cross-sectional view showing another exemplary fabricating process of a semiconductor package having the cross-section shown in FIG. 1B, consistent with some embodiments of the present disclosure.

FIGS. 8A through 8C are cross-sectional views showing another exemplary fabricating process of a semiconductor package having the cross-section shown in FIG. 1B, consistent with some embodiments of the present disclosure.

FIGS. 9 and 10 are cross-sectional views taken along line A-A′ of FIG. 1A, consistent with some embodiments of the present disclosure.

FIG. 11 is a plan view of another exemplary semiconductor package, consistent with some embodiments of the present disclosure.

FIG. 12 is a cross-sectional view taken along line D-D′ of FIG. 11, consistent with some embodiments of the present disclosure.

### DETAILED DESCRIPTION

Hereinafter, to explain the present disclosure more specifically, embodiments according to the present disclosure will be described in more detail with reference to the attached drawings.

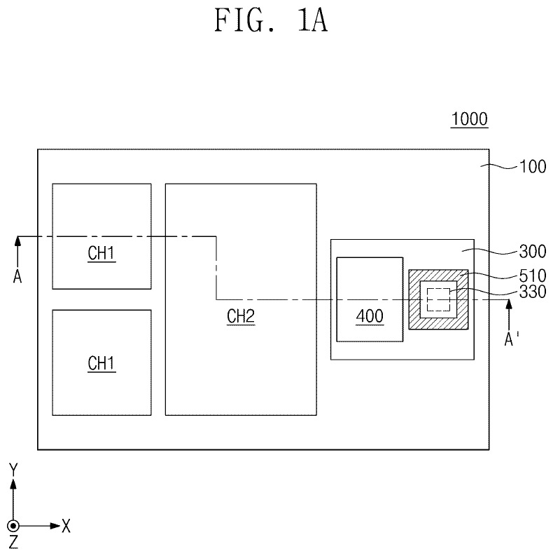

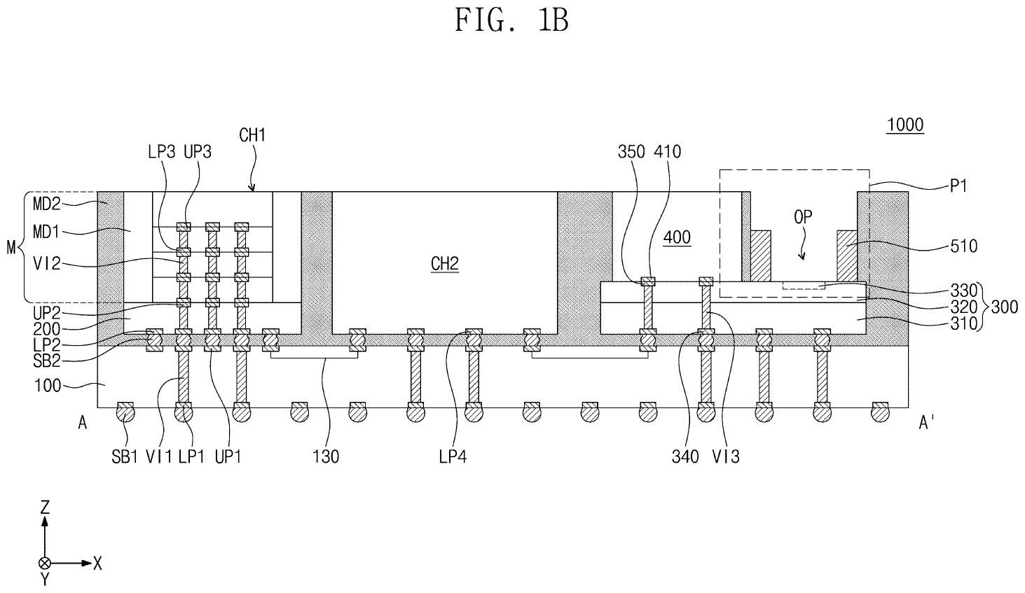

FIG. 1A is a plan view of an exemplary semiconductor package consistent with some embodiments of the present disclosure. FIG. 1B is an exemplary cross-sectional view taken along line A-A′ of FIG. 1A consistent with some embodiments of the present disclosure.

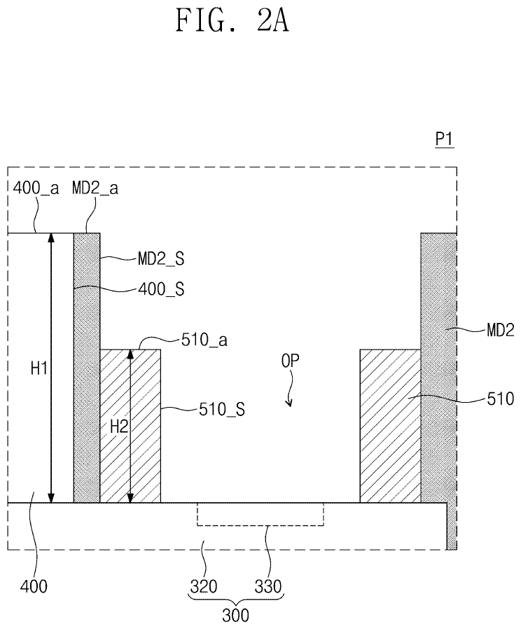

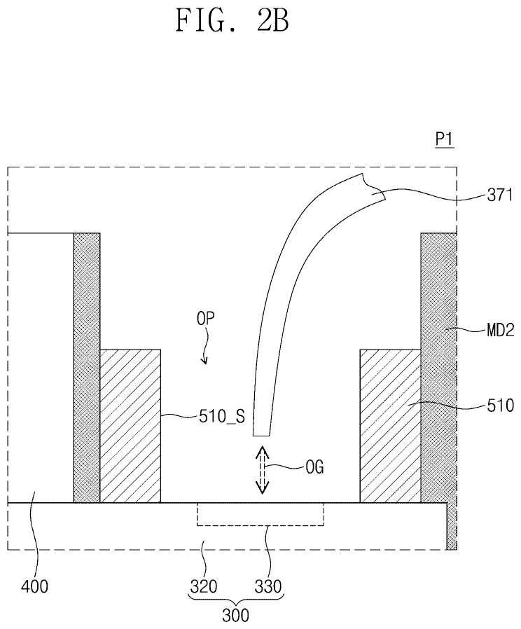

FIGS. 2A and 2B are exemplary enlarged views of portion ‘P1’ of FIG. 1B, consistent with some embodiments of the present disclosure.

Referring to FIGS. 1A and 1B, a semiconductor package 1000 consistent with some disclosed embodiments may include a first substrate 100, first semiconductor chips CH1, a second semiconductor chip CH2, and a photonics chip 300. The first semiconductor chips CH1, the second semiconductor chip CH2, and the photonics chip 300 may be disposed side by side and spaced apart from each other in a first direction X on the first substrate 100. The first semiconductor chips CH1 may be provided in the plural and may be disposed side by side in a second direction Y on one side of the second semiconductor chip CH2. For example, the number of the first semiconductor chips CH1 may be two or more. Unlike that which is shown in FIG. 1A, two or more first semiconductor chips CH1 may be disposed on each of two sides of the second semiconductor chip CH2. It will be understood that other variations are also possible.

The first substrate 100 may include a semiconductor material, glass, an organic material, another material, or a combination thereof. For example, the first substrate 100 may include silicon. As used herein, the term, “first substrate,” may be used interchangeably with the term, “interposer substrate.”

Referring to FIG. 1B, first upper conductive pads UP1 may be disposed on an upper surface of the first substrate 100. First lower conductive pads LP1 may be disposed on a lower surface of the first substrate 100. Each of the first upper conductive pads UP1 and the first lower conductive pads LP1 may have various shapes, such as a square, a rectangle, a circle, an oval, or another shape. Each of the first upper conductive pads UP1 and the first lower conductive pads LP1 may include a metal, such as, e.g., copper, gold, nickel, aluminum, tungsten, or titanium.

First connection members SB1 may be bonded to the first lower conductive pads LP1. The first connection members SB1 may connect the lower surface of the first substrate 100 and a printed circuit board (not shown). The first connection members SB1 may include a metal, and may include at least one of copper, nickel, tin, lead, or silver, for example.

First penetration vias VI1 may be provided in the plural to penetrate the first substrate 100. The first penetration vias VI1 may be connected to the corresponding first upper conductive pads UP1 and the first lower conductive pads LP1, respectively. The first penetration vias VI1 may include a metal such as copper, aluminum, or tungsten, for example. Although not illustrated, a first through-insulating layer (not shown) may be interposed between the first penetration vias VI1 and the first substrate 100. The first through-insulating layer (not shown) may have a single-layer or a multi-layer structure including at least one of silicon oxide, silicon nitride, and silicon oxynitride, and may also include an air gap region.

Although not illustrated, wirings (not shown) may be disposed on the first substrate 100. The wirings (not shown) may be formed of multilayer wiring patterns. The wirings (not shown) may serve to transmit signals between (1) the first and second semiconductor chips CH1, CH2 disposed on the upper surface of first substrate 100 and (2) the printed circuit board (not shown) connected to the lower surface of the first substrate 100.

Each of the first semiconductor chips CH1 may have, for example, a high bandwidth memory (HBM) chip structure. Each of the first semiconductor chips CH1 may include a buffer die 200, a plurality of semiconductor dies M, and a first mold layer MD1. The plurality of semiconductor dies M may be sequentially stacked on buffer die 200. The number of stacked buffer die 200 and semiconductor dies M may be different in different semiconductor packages 1000. For example, four, eight, twelve, more than 12, or a range between four and twelve semiconductor dies M may be stacked.

The buffer die 200 may be a base die including a semiconductor element.

Alternatively, the buffer die 200 may be referred to as an interface die, a logic die, a master die, etc. As used herein, the term “die” may also be referred to as a “chip.” The buffer die 200 may be, for example, a logic circuit chip. The buffer die 200 may operate as an interface circuit between the semiconductor dies M and an external controller. Alternatively, the buffer die 200 may be a memory chip such as a flash memory chip, a DRAM chip, an SRAM chip, an EEPROM chip, a PRAM chip, an MRAM chip, a ReRAM chip, or another chip. Alternatively, the buffer die 200 may be an interposer die that does not include a transistor.

The semiconductor dies M may be a different chip from the buffer die 200. In some exemplary embodiments, semiconductor dies M may be the same memory chips. The memory chips may be, for example, any one of a flash memory chip, a DRAM chip, an SRAM chip, an EEPROM chip, a PRAM chip, an MRAM chip, a ReRAM chip, or another chip. A width of the buffer die 200 may be greater than a width of the semiconductor dies M. Each of the buffer die 200 and the semiconductor dies M may include a substrate (not shown), an interlayer insulating layer (not shown), second penetration vias VI2, a transistor (not shown), and wirings (not shown). The substrate (not shown) may be, for example, a semiconductor single crystal substrate or a silicon on insulator (SOI) substrate.

Second upper conductive pads UP2 may be disposed on an upper surface of the buffer die 200. Second lower conductive pads LP2 may be disposed on a lower surface of the buffer die 200. Third upper conductive pads UP3 may be disposed on an upper surface of each of the semiconductor dies M. Third lower conductive pads LP3 may be disposed on a lower surface of each of the semiconductor dies M. The second upper conductive pads UP2 of the buffer die 200 and the lowermost of third lower conductive pads LP3 of the semiconductor dies M may be in contact with each other.

The second penetration vias VI2 may be provided in the plural to penetrate the substrates (not shown) of the buffer die 200 and the semiconductor dies M, respectively. The second penetration vias VI2 may be connected to corresponding second upper conductive pads UP2 and second lower conductive pads LP2, respectively. The second penetration vias VI2 may be connected to corresponding third upper conductive pads UP3 and third lower conductive pads LP3, respectively. The second penetration vias VI2 may include a metal such as copper, aluminum, or tungsten, for example.

The first mold layer MD1 may cover side surfaces of the semiconductor dies M and the upper surface of the buffer die 200. The first mold layer MD1 may include an insulating resin such as, for example, an epoxy-based molding compound (EMC). The first mold layer MD1 may further include a filler, and the filler may be dispersed in the insulating resin. The filler may include, for example, silicon oxide (SiO₂).

The second semiconductor chip CH2 may be, for example, a logic chip. The second semiconductor chip CH2 may be, e.g., an application-specific integrated circuit (ASIC) chip or a system on chip. The second semiconductor chip CH2 may also be referred to as a host, an application processor (AP), etc. The second semiconductor chip CH2 may receive commands, data, signals, etc., transmitted from an external controller, and may transmit the received commands, data, signals, etc., to the first semiconductor chips CH1. The second semiconductor chip CH2 may transmit data output from the first semiconductor chips CH1 to the external controller. The second semiconductor chip CH2 may include a memory controller that, e.g., controls the semiconductor dies M of the first semiconductor chips CH1 and performs data input/output associated with the semiconductor dies M.

The second semiconductor chip CH2 may include fourth lower conductive pads LP4, a substrate (not shown), an interlayer insulating layer (not shown), a transistor (not shown), and wirings (not shown). The substrate (not shown) may be, for example, a semiconductor single crystal substrate or a silicon on insulator (SOI) substrate.

The fourth lower conductive pads LP4 may be disposed on a lower surface of the second semiconductor chip CH2. Each of the first through third upper conductive pads UP1, UP2, UP3 and the first through fourth lower conductive pads LP1, LP2, LP3, LP4 may have various shapes, such as, e.g., a square, a rectangle, a circle, an oval, or another shape. Each of the first through third upper conductive pads UP1, UP2, UP3 and the first to fourth lower conductive pads LP1, LP2, LP3, LP4 may include a metal such as, for example, copper, gold, nickel, aluminum, tungsten, or titanium.

The photonics chip 300 may include a substrate layer 310, a device layer 320, and a transceiver 330. The substrate layer 310 may include, for example, silicon. However, the present disclosure is not limited thereto. The substrate layer 310 may further include an insulating oxide such as, for example, silicon oxide (SiO₂).

The device layer 320 may be disposed on the substrate layer 310. The device layer 320 may include, for example, semiconductor elements, wiring layers, and interlayer insulating layers. Photonics integrated circuits (or optical integrated circuits) that perform various roles may also be disposed on the device layer 320. The optical integrated circuits may include elements such as, e.g., semiconductor lasers, optical amplifiers, electrical signal amplifiers, optical modulators, optical waveguides, optical couplers, or optical detectors. The optical integrated circuits may act as transceivers that receive external light into an interior of the photonics chip 300 or that emit light from the photonics chip 300 to the outside (e.g., externally to semiconductor package 1000). The substrate layer 310 may include, for example, a III/V group compound semiconductor material or a II/VI group compound semiconductor material. The device layer 320 may include an insulating material. The transceiver 330 may be disposed on an upper portion of the device layer 320. The transceiver 330 may include elements such as micro lenses, optical lenses, or optical waveguides, for example.

An electronic circuit chip 400 may be disposed on the photonics chip 300. The electronic circuit chip 400 may be spaced apart from the transceiver 330 of the photonics chip 300 and, according to some embodiments, may not overlap the transceiver 330. The electronic circuit chip 400 may include an electronic integrated circuit therein. Although not illustrated, the electronic circuit chip 400 may include a substrate (not shown), an interlayer insulating layer (not shown), a transistor (not shown), and wirings (not shown). The substrate (not shown) may be, for example, a semiconductor single crystal substrate or a silicon on insulator (SOI) substrate.

First upper chip pads 350 may be disposed on an upper surface of the photonics chip 300. First lower chip pads 340 may be disposed on a lower surface of the photonics chip 300. Second lower chip pads 410 may be disposed on a lower surface of the electronic circuit chip 400. Each of the first upper chip pads 350 and the first and second lower chip pads 340, 410 may have various shapes, such as, e.g., a square, a rectangle, a circle, an oval, or another shape. Each of the first upper chip pads 350 and the first and second lower chip pads 340, 410 may include a metal, such as, e.g., copper, gold, nickel, aluminum, tungsten, or titanium.

The second lower chip pads 410 of the electronic circuit chip 400 may be in direct contact with the first upper chip pads 350 of the photonics chip 300, respectively. The first upper chip pads 350 and the second lower chip pads 410 may include the same material (or they may include different materials). The first upper chip pads 350 and the second lower chip pads 410 which are in contact with each other may be fused together to form an integral body among the first upper chip pads 350 and the second lower chip pads 410.

Third penetration vias VI3 may be provided in the plural to penetrate at least a portion of the substrate layer 310 or the device layer 320. The third penetration vias VI3 may be connected to corresponding first upper chip pads 350 and first lower chip pads 340, respectively. The third penetration vias VI3 may include a metal such as copper, aluminum, or tungsten, for example.

Referring to FIGS. 1A, 1B, and 2A, a second mold layer MD2 may cover the first substrate 100, the first and second semiconductor chips CH1, CH2, the photonics chip 300, and the electronic circuit chip 400. The second mold layer MD2 may cover side surfaces of the first and second semiconductor chips CH1, CH2, the photonics chip 300, and the electronic circuit chip 400. The second mold layer MD2 may cover at least a portion of an upper surface of the photonics chip 300.

The second mold layer MD2 may have an opening OP exposing the transceiver 330 on the upper surface of the photonics chip 300. The opening OP may expose at least a portion of the upper surface of the device layer 320. An inner wall MD2_S of the second mold layer MD2 may be exposed by the opening OP. One side wall 400_S of the electronic circuit chip 400 may be spaced apart from the inner wall MD2_S of the second mold layer MD2.

The second mold layer MD2 may include an insulating resin, such as, e.g., an epoxy-based molding compound (EMC). The second mold layer MD2 may further include a filler, and the filler may be dispersed in the insulating resin. The filler may include, for example, silicon oxide (SiO₂).

A wall structure 510 may be disposed in the opening OP and may be in contact with the upper surface of the photonics chip 300. The wall structure 510 may be in contact with the inner wall MD2_S of the second mold layer MD2 exposed to the opening OP. That is, the second mold layer MD2 may cover an outer wall of the wall structure 510. As illustrated in FIG. 1A, the wall structure 510 may not overlap the transceiver 330 and may be disposed to surround the transceiver 330 when viewed in a plan view. The wall structure 510 may have a closed ring shape when viewed in a plan view. Unlike the shape illustrated in FIG. 1A, the wall structure 510 may have various shapes, such as, e.g., a square, a rectangle, a circle, an oval, or another shape. An inner wall 510_S of the wall structure 510 may be exposed by the opening OP. The wall structure 510 may include, for example, at least one of metal or ceramic.

The upper surfaces of the first and second semiconductor chips CH1, CH2 and the electronic circuit chip 400 may be exposed. An upper surface 400_a of the electronic circuit chip 400 and an upper surface MD2_a of the second mold layer MD2 may be positioned at the same level. Upper surfaces of the first and second semiconductor chips CH1, CH2 may also be positioned at the same level as the upper surface MD2_a of the second mold layer MD2. The upper surface MD2_a of the second mold layer MD2 and an upper surface 510_a of the wall structure 510 may be stepped. The electronic circuit chip 400 and the second mold layer MD2 may have the same first height H1, and the wall structure 510 may have a second height H2 smaller than the first height H1.

Referring to FIGS. 1B and 2B, an optical fiber 371 may be connected to the transceiver 330. The optical fiber 371 may be directly or indirectly connected to the transceiver 330. For example, the optical fiber 371 may be connected to a micro lens, an optical lens, or an optical waveguide included in the transceiver 330 to receive external light (e.g., an optical signal and/or an optical output) into the interior of the photonics chip 300, or to emit light (e.g., an optical signal and/or an optical output) of the photonics chip 300 to the outside. In some exemplary embodiments, a structure that functions as a connector connecting the optical fiber 371 and the transceiver 330 may be disposed between the optical fiber 371 and the transceiver 330, unlike the structure illustrated in FIG. 2B. The optical fiber 371 may connect the semiconductor package 1000 to another external semiconductor chip or semiconductor package.

The optical signal and/or optical output may be transmitted through an optical transmission path OG between the transceiver 330 and the optical fiber 371. The wall structure 510 may surround the transceiver 330 while the wall structure 510 is spaced apart from the transceiver 330, thereby guiding the optical signal and/or optical output to the optical transmission path OG. As a result, the optical signal and/or optical output may be transmitted through the optical transmission path OG without distortion (e.g., reflection, refraction, etc.). Accordingly, the semiconductor package 1000 may operate without optical loss.

Referring to FIG. 1B, some members of second connection members SB2 may be bonded to the second lower conductive pads LP2 of the first semiconductor chips CH1 to connect the lower surface of the buffer die 200 and the first substrate 100. Other members of the second connection members SB2 may be bonded to the fourth lower conductive pads LP4 of the second semiconductor chip CH2 to connect the lower surface of the second semiconductor chip CH2 and the first substrate 100. The other members of the second connection members SB2 may be bonded to the first lower chip pads 340 of the photonics chip 300 to connect the lower surface of the photonics chip 300 and the first substrate 100. The second connection members SB2 may include a metal, and may include at least one of copper, nickel, tin, lead, or silver, for example.

The first substrate 100 may include connection wirings 130 therein. The first and second semiconductor chips CH1, CH2, the photonics chip 300, and the electronic circuit chip 400 may be electrically connected through the connection wirings 130. The connection wirings 130 may include, for example, one or more of copper, aluminum, silver, tin, gold, nickel, lead, or titanium.

The semiconductor package 1000 may receive an external optical signal into the interior of the photonics chip 300 through the optical fiber 371 and convert the optical signal into an electrical signal through the electronic circuit chip 400. The converted electrical signal may be transmitted from the second semiconductor chip CH2 to the semiconductor dies M of the first semiconductor chip CH1 through the connection wirings 130 of the first substrate 100. In addition, data output from the semiconductor dies M may be transmitted from the second semiconductor chip CH2 to the electronic circuit chip 400 through the connection wirings 130 of the first substrate 100. Thereafter, the signal may be transmitted from the electronic circuit chip 400 to the photonics chip 300, converted into an optical signal in the photonics chip 300, and then transmitted to the outside through the optical fiber 371.

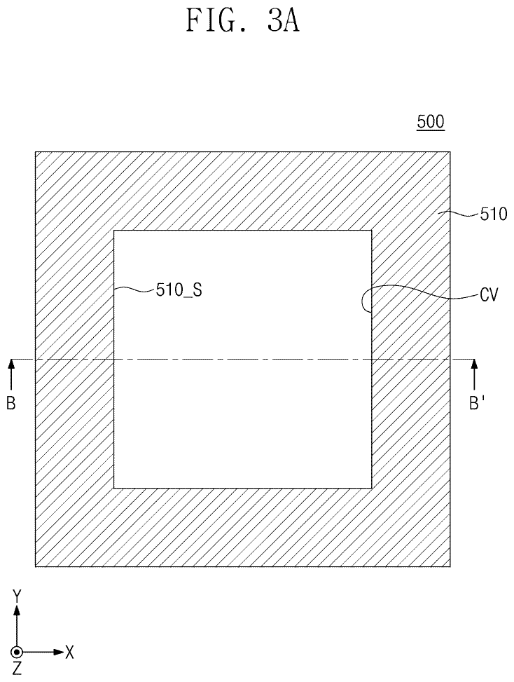

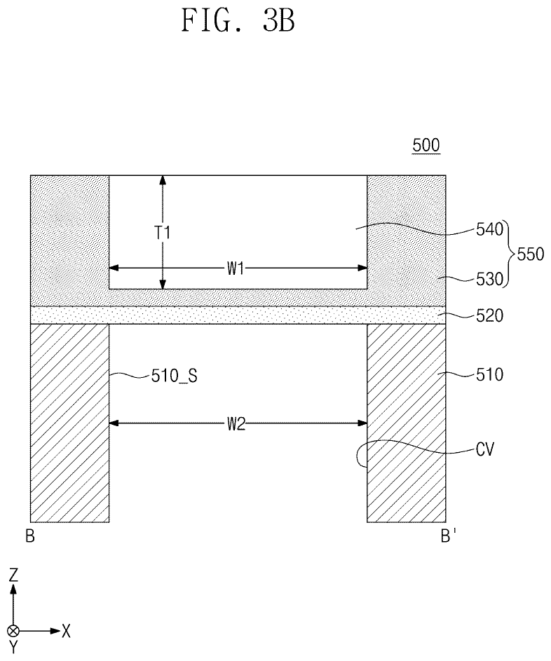

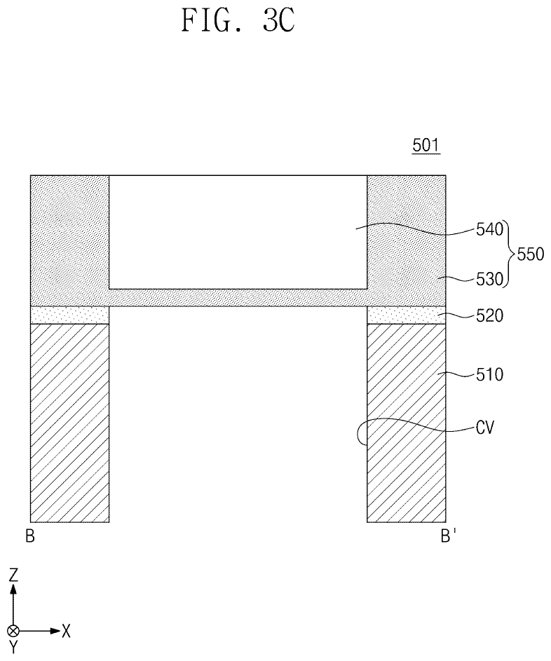

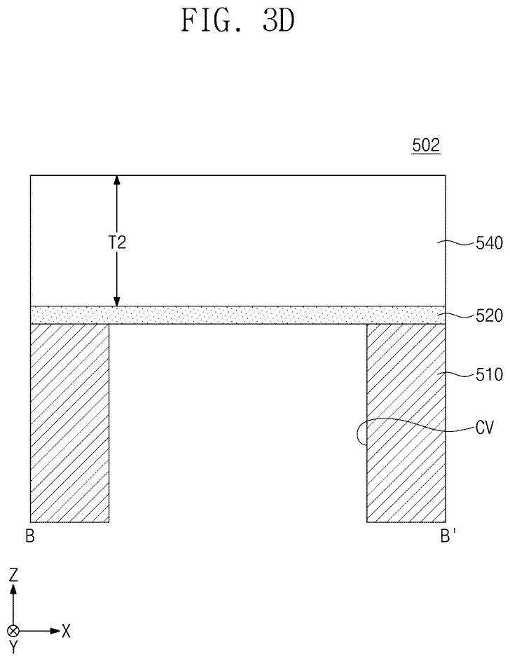

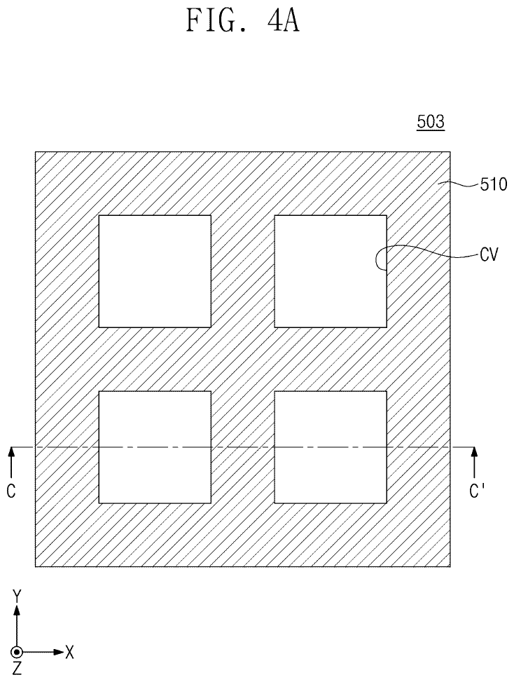

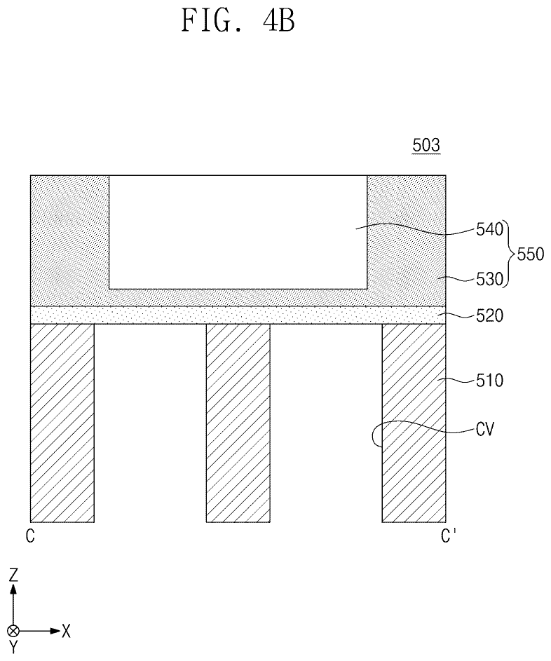

FIG. 3A is a bottom plan view of an exemplary protection block consistent with some embodiments of the present disclosure. FIGS. 3B through 3D are cross-sectional views taken along line B-B′ of FIG. 3A, consistent with some embodiments of the present disclosure. FIG. 4A is a bottom plan view of another exemplary protection block consistent with some embodiments of the present disclosure. FIG. 4B is a cross-sectional view taken along line C-C′ of FIG. 4A, consistent with some embodiments of the present disclosure.

Referring to FIGS. 3A and 3B, a protection block 500 according to the present embodiment may include a wall structure 510 and a support structure 550. The protection block 500 may include a cavity CV in the wall structure 510. The support structure 550 may be disposed on the wall structure 510. The support structure 550 may include a first sub-structure 530 and a second sub-structure 540 disposed in the first sub-structure 530. The first sub-structure 530 may include, for example, at least one of an epoxy resin, a ceramic, or another material. The second sub-structure 540 may include, for example, silicon, glass, or an organic material.

A first width W1 of the second sub-structure 540 may be smaller than or equal to a second width W2 of a distance between inner walls 510_S of the wall structure 510. The second sub-structure 540 may be disposed on the cavity CV and, consistent with some embodiments, may not be disposed on the wall structure 510. A first thickness T1 of the second sub-structure 540 may range from, e.g., 15 μm to 50 μm.

An adhesive member 520 may be interposed between the first sub-structure 530 and the wall structure 510. The adhesive member 520 may include, for example, a die attach film (DAF), an epoxy resin, an ultraviolet-curable material, an ultraviolet-noncurable material, an acrylic polymer, or another material. The adhesive member 520 may have a multilayer structure (e.g., a base layer, an adhesive layer, a release layer, etc.). The adhesive member 520 may cover a lower surface of the first sub-structure 530.

Referring to FIG. 3C, a protection block 501 consistent with some disclosed embodiments may have a structure in which the adhesive member 520 is disposed differently on the wall structure 510, the wall structure 510 having a similar structure as that shown in FIG. 3B. The adhesive member 520 may be interposed between the first sub-structure 530 and the wall structure 510, and, consistent with some embodiments, may not cover a lower surface of the first sub-structure 530 exposed to the cavity CV. The other configurations may be the same as or similar to those described with reference to FIGS. 1A through 3B.

Referring to FIG. 3D, a protection block 502 consistent with some embodiments may have the second sub-structure 540 disposed on the wall structure 510. In some embodiments, when a second thickness T2 of the second sub-structure 540 is greater than the first thickness T1 of the second sub-structure shown in FIG. 3B, the protection block 502 may not include the first sub-structure 530 (or any other first sub-structure). The second sub-structure 540 may be extended to be disposed on the cavity CV and the wall structure 510. The adhesive member 520 may be interposed between the second sub-structure 540 and the wall structure 510. The adhesive member 520 may cover the lower surface of the second sub-structure 540. The other configurations may be the same as or similar to those described with reference to FIGS. 1A through 3C.

Referring to FIGS. 4A and 4B, a protection block 503 consistent with some embodiments may have a lattice shape when viewed in a plan view and may include a plurality of cavities CV in the wall structure 510. The other configurations may be the same as or similar to those described with reference to FIGS. 1A through 3B.

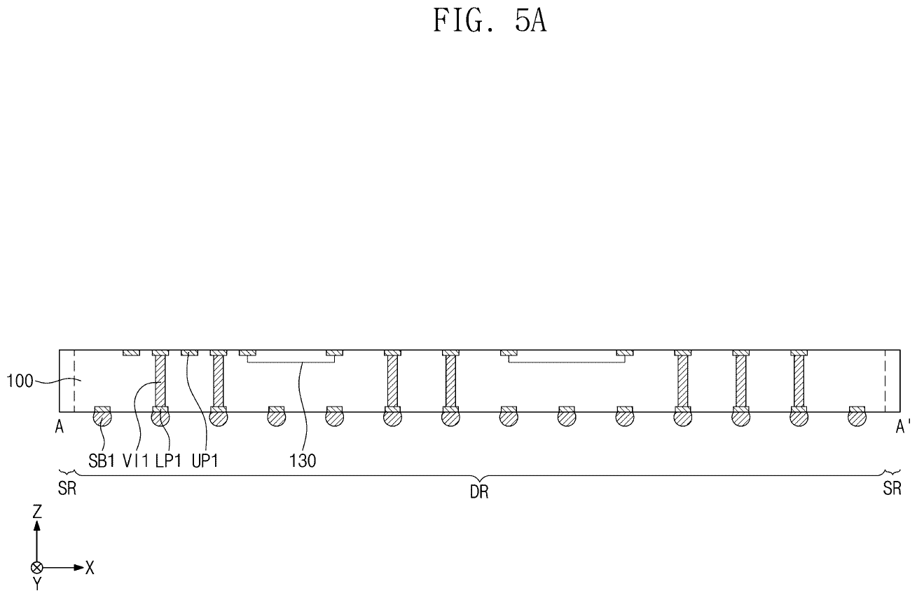

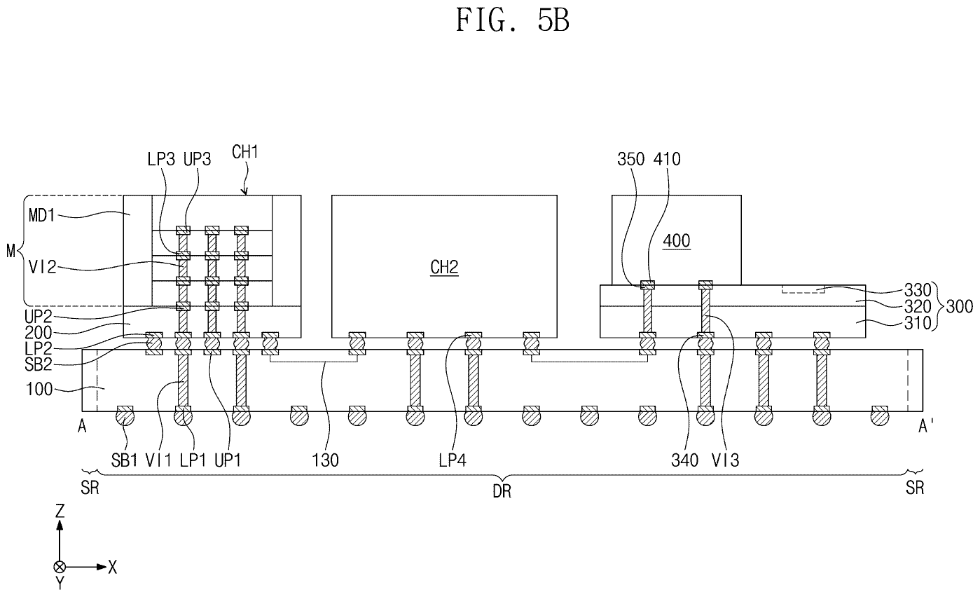

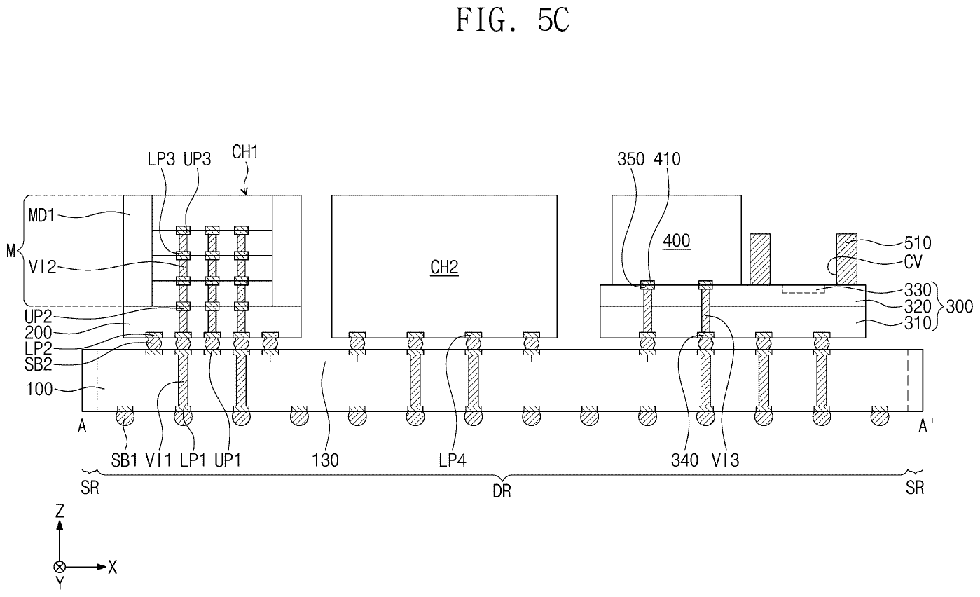

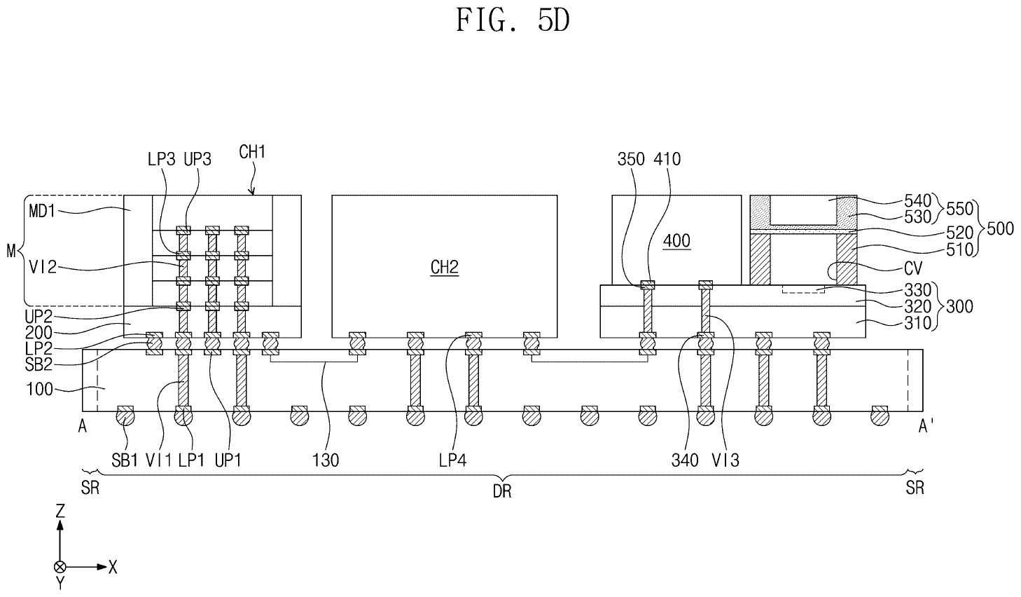

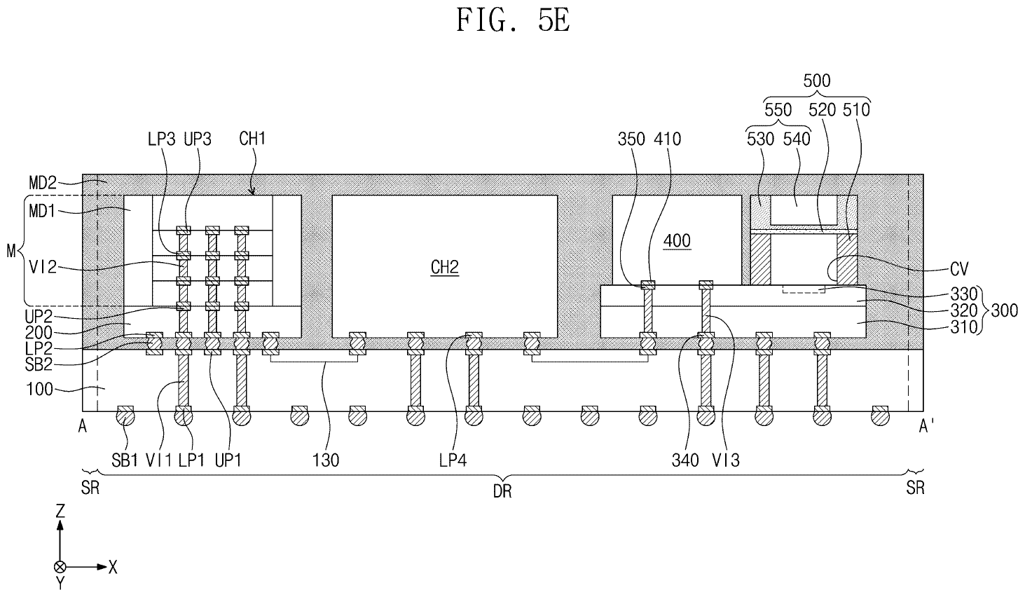

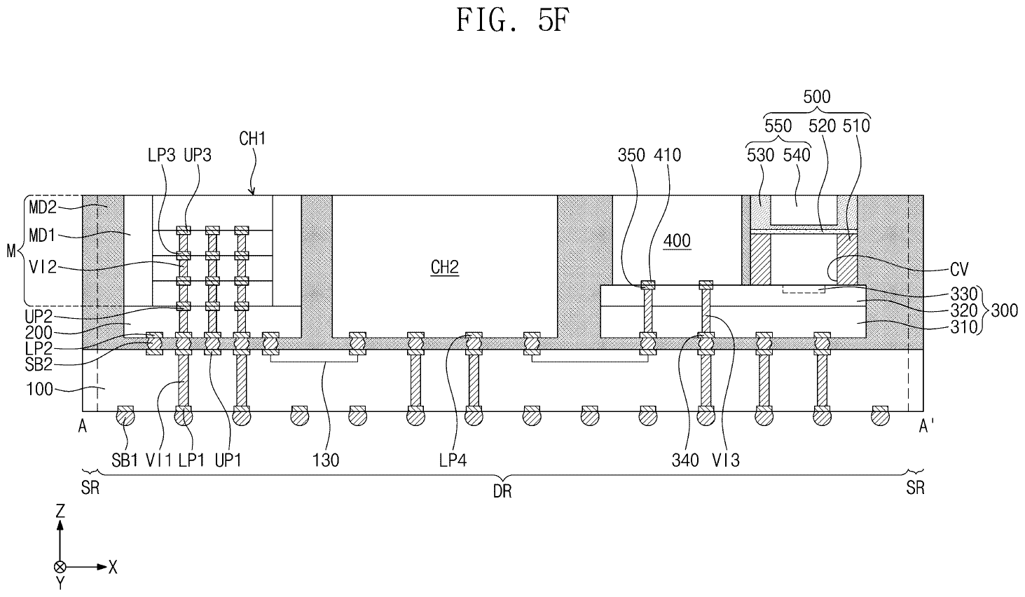

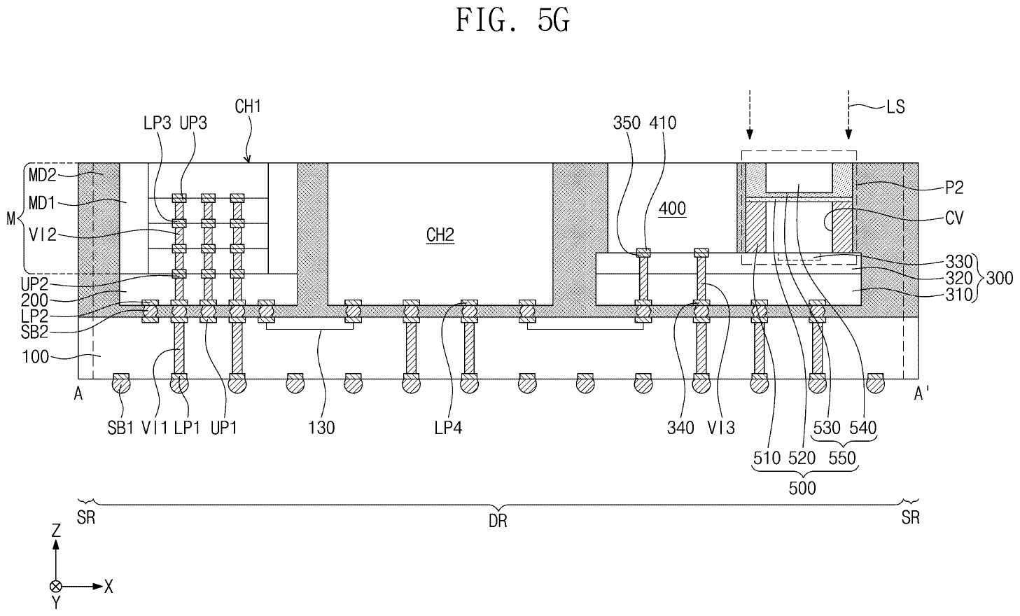

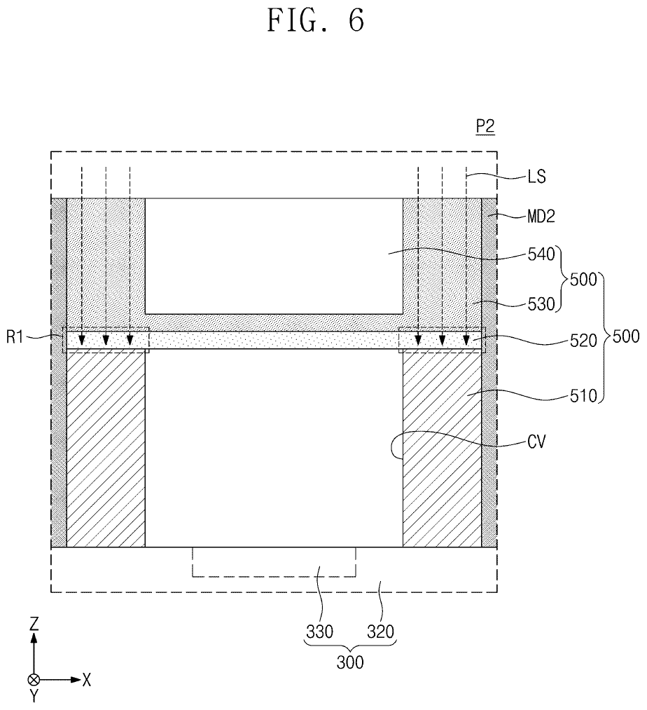

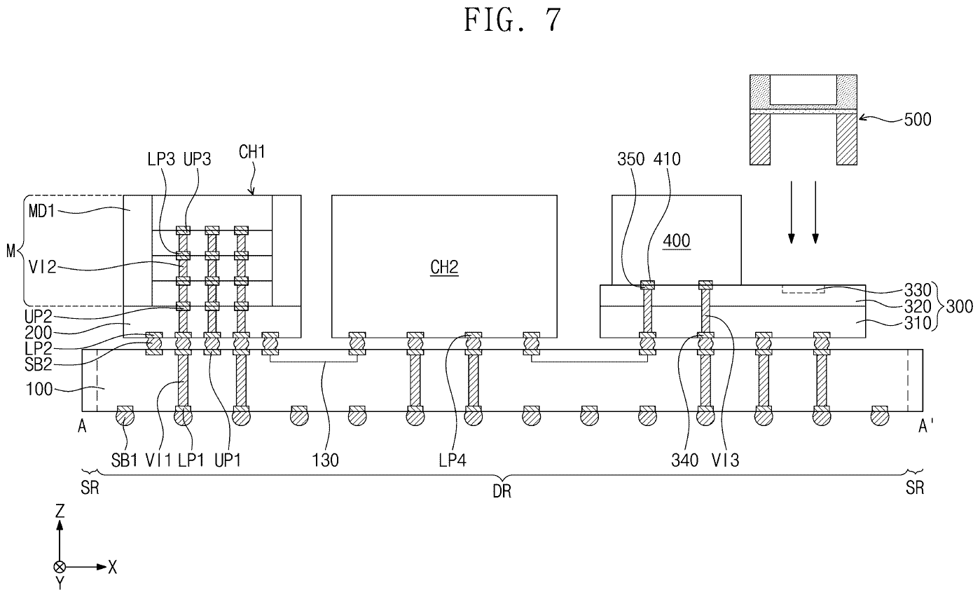

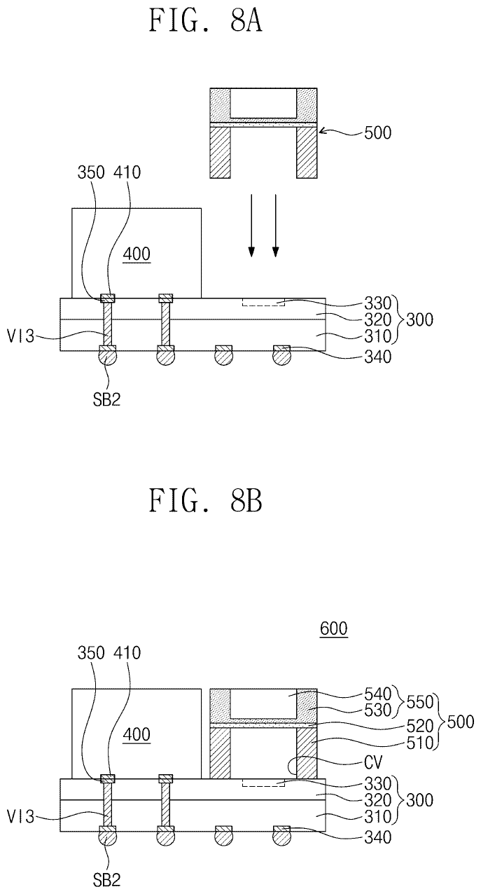

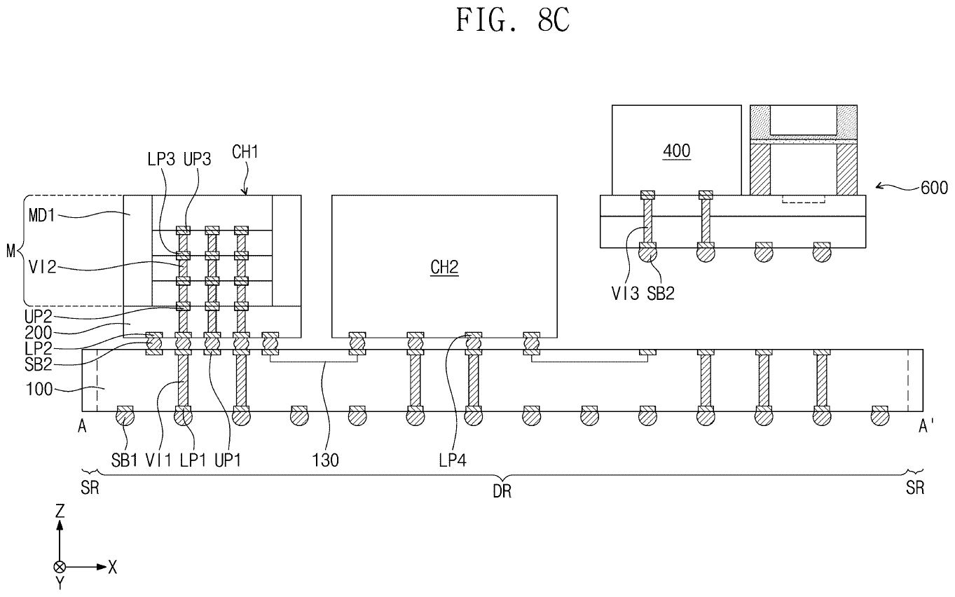

FIGS. 5A through 5G are cross-sectional views sequentially showing an exemplary fabricating process of a semiconductor package having the cross-section shown in FIG. 1B, consistent with some embodiments. FIG. 6 is an enlarged view of portion ‘P2’ of FIG. 5G. FIG. 7 is a cross-sectional view showing another exemplary fabricating process of a semiconductor package having the cross-section shown in FIG. 1B, consistent with some embodiments. FIGS. 8A through 8C are cross-sectional views showing another fabricating process of a semiconductor package having the cross-section shown in FIG. 1B, consistent with some embodiments. Hereinafter, disclosure that is common to FIGS. 5A-5G, 6, 7, and 8A-8C will be presented once and will not be repeated.

Referring to FIG. 5A, and according to some embodiments, the first substrate 100 may be prepared. The first substrate 100 may be provided as a wafer. The first substrate 100 may have a chip region DR and a separation region SR. The chip region DR may have a structure of the first substrate 100 as described with reference to FIGS. 1A and 1B. The separation region SR may be, e.g., a scribe lane region.

First penetration vias VI1, first upper conductive pads UP1, first lower conductive pads LP1, connection wirings 130, and first connection members SB1 may be formed on the chip region DR of the first substrate 100.

Referring to FIG. 5B, a photonics chip 300 in which an electronic circuit chip 400 is bonded to the upper surface thereof may be prepared. And the first and second semiconductor chips CH1 and CH2 may be prepared separate from the first substrate 100.

A substrate (not shown), an interlayer insulating layer (not shown), second penetration vias VI2, a transistor (not shown), and wirings (not shown) may be formed on each of a buffer die 200 and semiconductor dies M. Second upper conductive pads UP2 may be formed on an upper surface of the buffer die 200, and second lower conductive pads LP2 may be formed on a lower surface of the buffer die 200. Third upper conductive pads UP3 and third lower conductive pads LP3 may be formed on an upper surface of each of the semiconductor dies M. According to some embodiments, third upper conductive pads UP3 may not be formed on the uppermost ones of semiconductor dies M. After stacking the semiconductor dies M on the buffer die 200, the semiconductor dies M may be bonded to the buffer die 200 through a thermal compression process, a first mold layer MD1 covering them may be formed, and then a plurality of first semiconductor chips CH1 may be formed through a dicing process.

A substrate (not shown), a transistor (not shown), wirings (not shown), an interlayer insulating layer (not shown), and fourth lower conductive pads LP4 may be formed on the second semiconductor chip CH2.

A substrate layer 310 and a device layer 320 on the substrate layer 310 may be formed in a form of a wafer. Transceivers 330 and first upper chip pads 350 may be formed on the device layer 320, and first lower chip pads 340 may be formed on a lower surface of the substrate layer 310. Third penetration vias VI3 which penetrate at least a portion of the substrate layer 310 or the device layer 320 may be formed. Thereafter, electronic circuit chips 400 having second lower chip pads 410 formed on the lower surface thereof may be bonded to the device layer 320. After the second lower chip pads 410 of the electronic circuit chips 400 are in contact with the first upper chip pads 350 of the device layer 320, direct bonding therebetween may be performed through a thermal compression process. In this case, a direct bonding process or hybrid copper bonding, for example, may be performed. Afterwards, a plurality of photonics chips 300 having an electronic circuit chip 400 bonded to the upper surface thereof may be formed through a sawing process.

After forming the first and second semiconductor chips CH1, CH2 and the photonics chip 300, the first and second semiconductor chips CH1, CH2 and the photonics chip 300 may be bonded on the first substrate 100 in a flip-chip bonding manner. After the second connection members of each of the first and second semiconductor chips CH1, CH2 and the photonics chip 300 overlap the first upper conductive pads UP1 of the first substrate 100, a thermocompression process may be performed to bond the first and second semiconductor chips CH1 and CH2, and the photonics chip 300 on the first substrate 100. Alternatively, the first and second semiconductor chips CH1 and CH2, and the photonics chip 300 may be sequentially bonded on the first substrate 100.

Referring to FIG. 5C, in some embodiments, the wall structure 510 may be spaced apart from the electronic circuit chip 400 and may be attached to the photonics chip 300. The wall structure 510 may have a cavity CV therein and may expose the transceiver 330. Referring to FIGS. 3B and 5D, a support structure 550 may be attached to a wall structure 510 by interposing an adhesive member 520 therebetween to form a protection block 500. The support structure 550 may include a first sub-structure 530 and a second sub-structure 540 disposed in the first sub-structure 530. A first width W1 of the second sub-structure 540 may be formed to be smaller than or equal to a second width W2 of a distance between inner walls 510_S of the wall structure 510. A first thickness T1 of the second sub-structure 540 may range from, e.g., 15 μm to 50 μm. The support structure 550 may, e.g., cover the cavity CV.

Referring to FIG. 5E, a molding process may be performed to form a second mold layer MD2 covering the first substrate 100, the first and second semiconductor chips CH1 and CH2, the photonics chip 300, the electronic circuit chip 400, and the protection block 500.

Referring to FIG. 5F, a grinding or chemical mechanical polishing (CMP) process may be performed to remove at least a portion of the first and second semiconductor chips CH1 and CH2, the electronic circuit chip 400, the first and second sub-structures 530, 540, and/or the second mold layer MD2. Upper surfaces of the first and second semiconductor chips CH1 and CH2, the electronic circuit chip 400, and/or the first and second sub-structures 530, 540 may be exposed. The upper surfaces of the first and second semiconductor chips CH1 and CH2, the electronic circuit chip 400, the first and second sub-structures 530, 540, and/or the second mold layer MD2 may be positioned at the same level.

In such a case, a thickness of the first and second semiconductor chips CH1 and CH2, the electronic circuit chip 400, the first and second sub-structures 530, 540, and/or the second mold layer MD2 that is removed may range from, for example, 5 μm to 15 μm. In FIG. 5D, as the first thickness T1 of the second sub-structure 540 is formed to be greater than the above thickness, the second sub-structure 540 covering the cavity CV of the wall structure 510 may remain after the grinding or CMP process is performed. Therefore, while the grinding or CMP process is in progress, the support structure 550 may prevent foreign substances such as, e.g., slurry from flowing into the cavity CV. As a result, the protection block 500 may prevent contamination of the transceiver 330 of the photonics chip 300, thereby increasing yield.

The second sub-structure 540 may include, for example, silicon, glass, or an organic material, or another material. As the second sub-structure 540 includes a material having similar rigidity and ductility to the first and second semiconductor chips CH1 and CH2 and to the electronic circuit chip 400, the grinding or CMP process may be performed more easily. As the support structure 550 is disposed on the wall structure 510, a step between the first and second semiconductor chips CH1 and CH2, the electronic circuit chip 400, and the support structure 550 may be reduced, thereby preventing cracks and preventing damage to a grinding wheel of a substrate processing device used in the grinding or CMP process. Accordingly, yield of the semiconductor package may be increased.

Referring to FIGS. 1B, 5G, and 6, light LS may be irradiated onto the adhesive member 520 to deteriorate or harden the adhesive member 520 and separate the adhesive member 520 and the support structure 550 from the wall structure 510. The light LS may be, for example, ultraviolet (UV) light or a laser. For example, when using a laser, the light LS may be selectively irradiated onto the adhesive member 520 disposed in the first region R1 on the wall structure 510. As another example, when using ultraviolet (UV) light, the light LS may be irradiated onto the entirety of the adhesive member 520 or the light LS may be selectively irradiated onto the adhesive member 520 disposed in the first region R1 on the wall structure 510 using a mask pattern (not shown). However, the present disclosure is not limited thereto, and the adhesive member 520 and the support structure 550 may be separated from the wall structure 510 using, e.g., a physical method.

When the adhesive member 520 and the support structure 550 are removed, an opening OP may be formed, as shown in FIG. 1B. In such a case, as the support structure 550 protects the transceiver 330, a process for cleaning the inside of the opening OP may not be necessary.

Thereafter, a dicing process using a laser may be performed on the first substrate 100 to remove the separation region SR and form a plurality of semiconductor packages. The plurality of semiconductor packages may, e.g., have a structure that is the same as or similar to the semiconductor package 1000 described in FIGS. 1A through 2B.

Referring to FIGS. 5B and 7, in another exemplary fabrication process, the photonics chip 300 in which the electronic circuit chip 400 is bonded to the upper surface thereof may be bonded on the first substrate 100 using a flip-chip bonding manner. And the first and second semiconductor chips CH1 and CH2 may be bonded on the first substrate 100 using a flip-chip bonding manner. Then, a protection block 500 spaced apart from the electronic circuit chip 400 may be attached to the photonics chip 300 to form the exemplary structure shown in FIG. 5D. The subsequent processes may be the same as or similar to those described with reference to FIGS. 5E through 6.

Referring to FIGS. 8A and 8B, in another exemplary fabrication process, photonics chip 300 and an electronic circuit chip 400 may be formed in the same manner as described in FIG. 5B, and the electronic circuit chip 400 may be bonded on the photonics chip 300. Thereafter, a protection block 500 spaced apart from the electronic circuit chip 400 may be attached on the photonics chip 300 to form a photonics structure 600.

Referring to FIG. 8C, in another exemplary fabrication process, the first and second semiconductor chips CH1 and CH2 may be bonded on the first substrate 100 in a flip-chip bonding manner. Thereafter, the photonics structure 600 may be bonded on the first substrate 100 in a flip-chip bonding manner to form the exemplary structure of FIG. 5D. The subsequent processes may be the same as or similar to those described with reference to FIGS. 5E through 6.

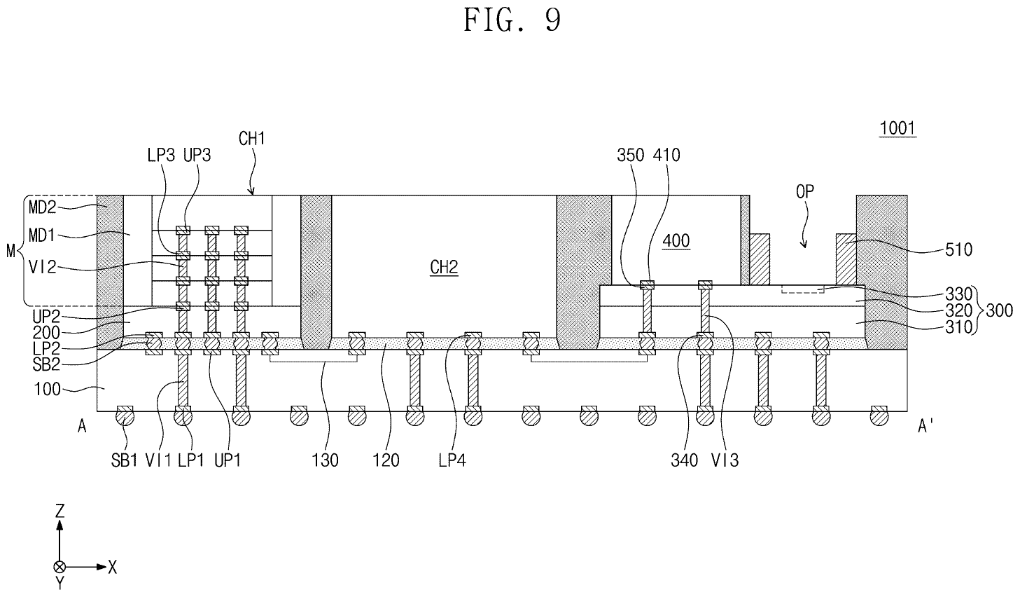

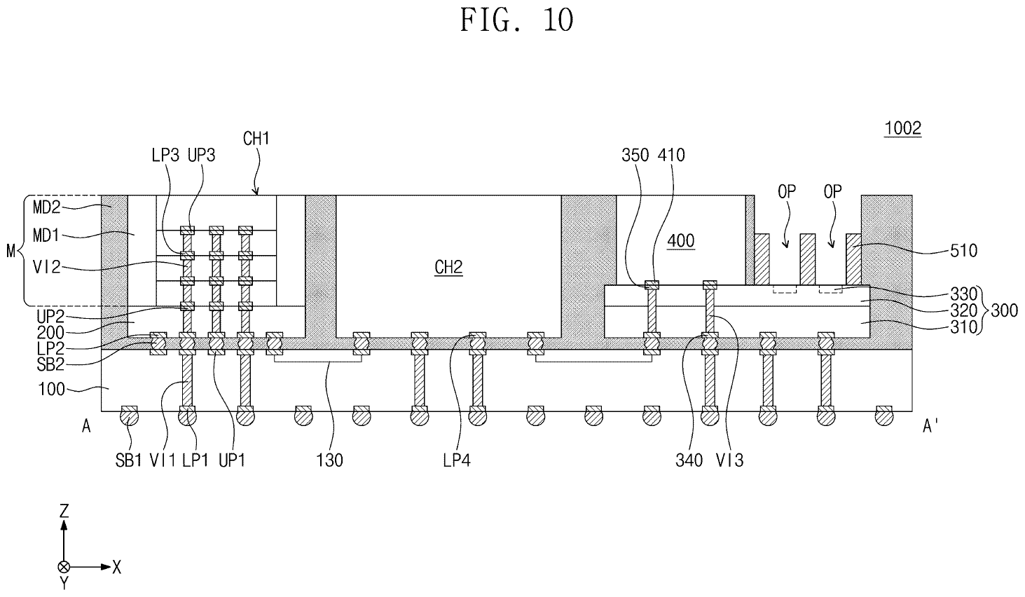

FIGS. 9 and 10 are cross-sectional views taken along line A-A′ of FIG. 1A consistent with some embodiments of the present disclosure.

Referring to FIG. 9, a semiconductor package 1001 consistent with some embodiments may have an underfill 120 interposed between a first substrate 100 and a first semiconductor chip CH1, between a first substrate 100 and a second semiconductor chip CH2, and between a first substrate 100 and a photonics chip 300. The underfill 120 may include, for example, an epoxy resin and may protect the second connection members SB2. The other configurations may be the same as or similar to those described with reference to FIGS. 1A through 2B.

Referring to FIGS. 2B, 4A, and 10, and consistent with some embodiments, a semiconductor package 1002 may be provided with a plurality of transceivers 330. The transceivers 330 may be spaced apart from each other and disposed on a device layer 320 of a photonics chip 300. A wall structure 510 may be spaced apart from the transceivers 330 and disposed to surround the transceivers 330 on the photonics chip 300. A plurality of openings OP may be provided in a wall structure 510. The openings OP may expose each of the transceivers 330, respectively. The wall structure 510 may have a lattice shape when viewed in a plan view, e.g., as illustrated in FIG. 4A. As further shown in FIG. 2B, the optical signals and/or optical outputs transmitted and received from each of the transceivers 330 through one of the openings OP may be guided to the optical transmission path OG without distortion (e.g., reflection, refraction, etc.). As a result, the semiconductor package 1002 may operate without optical loss. The other configurations may be the same as or similar to those described with reference to FIGS. 1A through 2B.

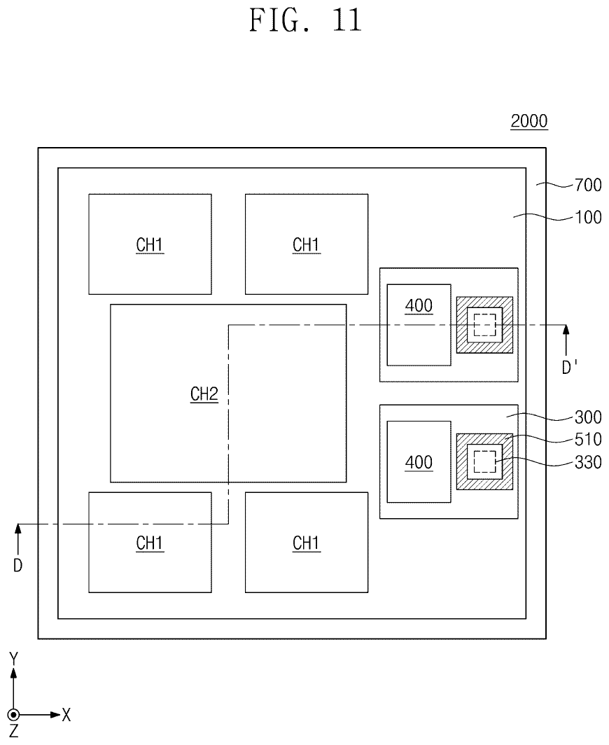

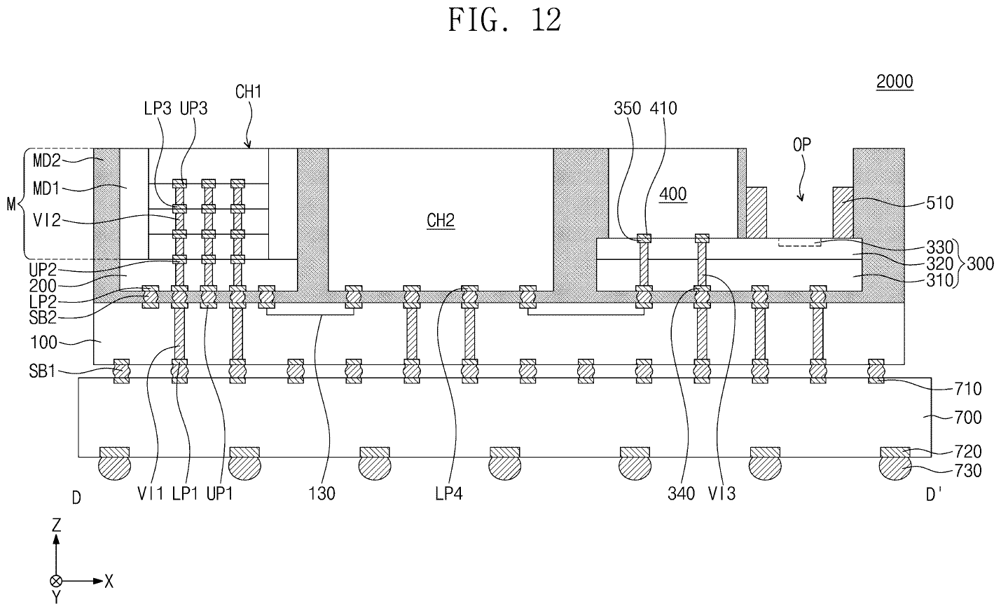

FIG. 11 is a plan view of an exemplary semiconductor package consistent with some embodiments of the present disclosure. FIG. 12 is a cross-sectional view taken along line D-D′ of FIG. 11, consistent with some embodiments of the present disclosure.

Referring to FIGS. 11 and 12, a semiconductor package 2000 consistent with some embodiments may include a package substrate 700. The package substrate 700 may be disposed, e.g., under the first substrate 100. The package substrate 700 may be, for example, a double-sided or multi-layer printed circuit board.

Package upper pads 710 may be disposed on an upper surface of the package substrate 700, and package lower pads 720 may be disposed on a lower surface of the package substrate 700. Each of the package upper pads 710 and the package lower pads 720 may include a metal such as, e.g., copper, gold, nickel, aluminum, tungsten, or titanium. First connection members SB1 may be bonded to the package upper pads 710 to connect the lower surface of the first substrate 100 and the package substrate 700. External connection members 730 may be bonded to the package lower pads 720. The external connection members 730 may include a metal such as, e.g., nickel, tin, lead, or silver.

The first semiconductor chips CH1 may be provided in the plural and, e.g., two semiconductor chips CH1 may be disposed on each side of the second semiconductor chip CH2. However, unlike that which is shown in the drawings, first semiconductor chips CH1 may be disposed in amounts of two or more on each side of the second semiconductor chip CH2. The photonics chips 300 on which the wall structures 510 are disposed may be provided in the plural and disposed, e.g., on different sides of the second semiconductor chip CH2. For example, the photonics chips 300 may be disposed in amounts of two or more. The photonics chips 300 may be disposed spaced apart from the first and second semiconductor chips CH1 and CH2. The other configurations may be the same as or similar to those described with reference to FIGS. 1A through 2B.

In the semiconductor packages described herein, as the wall structure surrounds the transceiver of the photonics chip, the optical signal and/or the optical output may be guided through the optical transmission path between the photonics chip and the optical fiber, thereby allowing the semiconductor package to operate without optical loss.

In the methods of fabricating the semiconductor package described herein, during the grinding or the CMP process, the protection block may prevent the inflow of the foreign substances such as, e.g., slurry, thereby preventing the contamination of the transceiver of the photonics chip. In addition, the protection block may reduce the step between the semiconductor chips, thereby preventing cracks and preventing damage to the grinding wheel of any substrate processing device. Accordingly, the yield of the semiconductor package may be increased.

While some embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor package comprising:
a first semiconductor chip;
a second semiconductor chip disposed on the first semiconductor chip;
a wall structure disposed on the first semiconductor chip and spaced apart from the second semiconductor chip in a first direction; and
a mold layer covering the first and second semiconductor chips,
wherein the first semiconductor chip includes a transceiver disposed thereon, the transceiver being spaced apart from the second semiconductor chip,
wherein the mold layer has an opening configured to expose the transceiver,
wherein the wall structure is disposed in the opening and is in contact with an inner wall of the mold layer exposed to the opening,
wherein the mold layer has a first height, and
wherein the wall structure has a second height smaller than the first height.

2. The semiconductor package of claim 1, further comprising a third semiconductor chip spaced apart from the first semiconductor chip in the first direction,
wherein the third semiconductor chip includes a plurality of stacked semiconductor dies.

3. The semiconductor package of claim 1, wherein the first semiconductor chip includes:
a substrate layer; and
a device layer on the substrate layer,
wherein the transceiver is disposed on the device layer, and
wherein the transceiver receives an external optical signal or transmits an optical signal externally.

4. The semiconductor package of claim 1, wherein an upper surface of the second semiconductor chip is exposed and positioned at a same level as an upper surface of the mold layer.

5. The semiconductor package of claim 1, wherein one sidewall of the second semiconductor chip is spaced apart from the inner wall of the mold layer.

6. The semiconductor package of claim 1, wherein an inner wall of the wall structure is exposed by the opening.

7. The semiconductor package of claim 1, wherein the wall structure is spaced apart from the transceiver and surrounds the transceiver when viewed in a plan view.

8. The semiconductor package of claim 7, wherein the wall structure has a closed ring shape when viewed in the plan view.

9. The semiconductor package of claim 7, wherein the wall structure has a lattice shape when viewed in the plan view and includes a plurality of openings, and
wherein the transceiver includes a plurality of transceivers, each of the transceivers being disposed below a respective one of the openings of the wall structure.

10. The semiconductor package of claim 1, wherein the wall structure includes at least one of a metal and a ceramic.

11. A semiconductor package comprising:
a photonics chip;
an electronic circuit chip disposed on the photonics chip;
a wall structure disposed on the photonics chip and spaced apart from the electronic circuit chip; and
a mold layer covering the photonics chip and the electronic circuit chip,
wherein the photonics chip includes a transceiver disposed on an upper portion thereof, the transceiver being spaced apart from the electronic circuit chip, wherein the mold layer has an opening configured to expose the transceiver,
wherein the wall structure is disposed in the opening and is in contact with an inner wall of the mold layer exposed to the opening, and
wherein the wall structure is spaced apart from the transceiver and has a closed ring shape that surrounds the transceiver when viewed in a plan view.

12. The semiconductor package of claim 11, wherein an upper surface of the electronic circuit chip is exposed and positioned at a same level as an upper surface of the mold layer.

13. The semiconductor package of claim 12, wherein the mold layer has a first height, and
wherein the wall structure has a second height that is smaller than the first height.

14. The semiconductor package of claim 11, wherein the photonics chip further includes upper chip pads on an upper surface thereof,
wherein the electronic circuit chip further includes lower chip pads on a lower surface thereof,
wherein the upper chip pads are in contact with respective ones of the lower chip pads, and
wherein the upper chip pads and the lower chip pads include a same material.

15. The semiconductor package of claim 11, wherein one sidewall of the electronic circuit chip is spaced apart from an inner sidewall of the mold layer.

16. The semiconductor package of claim 11, wherein an inner sidewall of the wall structure is exposed by the opening.

17. The semiconductor package of claim 11, wherein the wall structure includes at least one of a metal or a ceramic.

18. A semiconductor package comprising:
a package substrate;
a first substrate disposed on the package substrate;
first and second semiconductor chips and a photonics chip disposed side by side in a first direction on the first substrate;
an electronic circuit chip on the photonics chip;
a wall structure disposed on the photonics chip and spaced apart from the electronic circuit chip in the first direction; and
a mold layer covering the first and second semiconductor chips, the photonics chip, and the electronic circuit chip,
wherein the first semiconductor chip includes a plurality of stacked semiconductor dies,
wherein the photonics chip includes a transceiver on an upper portion thereof, the transceiver being spaced apart from the electronic circuit chip,
wherein the mold layer has an opening configured to expose the transceiver,
wherein the wall structure is disposed in the opening and is in contact with an inner wall of the mold layer exposed to the opening,
wherein an upper surface of the electronic circuit chip is positioned at a same level as an upper surface of the mold layer, and
wherein a step is provided between an upper surface of the mold layer and an upper surface of the wall structure.

19. The semiconductor package of claim 18, wherein the first semiconductor chip includes a plurality of first semiconductor chips disposed on one side of the second semiconductor chip, and
wherein the photonics chip includes a plurality of photonics chips disposed on another side of the second semiconductor chip.

20. The semiconductor package of claim 18, wherein the mold layer has a first height, and
wherein the wall structure has a second height smaller than the first height.
